(19) United States
(12) Patent Application Publication
(10) Pub. No.: US 2024/0244861 A1
(43) Pub. Date: Jul. 18, 2024

(54) QUANTUM DOT LIGHT-EMITTING DEVICES AND METHODS OF PREPARING THE SAME, DISPLAY SUBSTRATES, AND DISPLAY APPARATUSES

(71) Applicants: Beijing BOE Technology Development Co., Ltd., Beijing (CN); BOE Technology Group Co., Ltd., Beijing (CN)

(72) Inventor: Dong LI, Beijing (CN)

(21) Appl. No.: 17/921,545

(22) PCT Filed: Oct. 28, 2021
(86) PCT No.: PCT/CN2021/127191

§ 371 Date: Oct. 26, 2022

(51) Int. Cl. H10K 50/115; H10K 85/60

(52) U.S. Cl. CPC H10K 50/115; H10K 85/653; H10K 85/654

(57) ABSTRACT

The present disclosure relates to a quantum dot light-emitting device and a method of preparing the same, a display substrate, and a display apparatus. The quantum dot light-emitting device includes a first electrode layer, a light-emitting layer, and a second electrode layer, the light-emitting layer being provided between the first electrode layer and the second electrode layer, and the light-emitting layer including quantum dots and electrolytes, where the quantum dots are provided between the electrolytes in a direction from the first electrode layer to the second electrode layer; and the electrolytes undergo an electrochemical reaction in the presence of an electric field to provide an equal number of electrons and holes. According to the embodiments of the present disclosure, the electrons and holes injected into the quantum dots can be balanced, which is conducive to improving imbalance of carriers injected into the quantum dot light-emitting device, and thus improving the light-emitting efficiency of the quantum dot light-emitting device.

### TECHNICAL FIELD

This application relates to the field of display technology, and in particular to quantum dot light-emitting devices and methods of preparing the same, display substrates, and display apparatuses.

### BACKGROUND

In the related art, quantum dots (QDs), as a new light-emitting material, have advantages such as high light color purity, high light-emitting quantum efficiency, adjustable light-emitting color, and long service life, and have become a new type of light-emitting material for light-emitting diodes (LEDs). LEDs with quantum dots as a light-emitting layer are called quantum dot light-emitting diodes (QLEDs). QLEDs have become a research direction for new display devices.

However, in QLEDs, electron injection is generally superior to hole injection in quantum dots (especially those emitting red and green light) due to energy level positions and other reasons, and electrons are dominant in the number of carriers, resulting in imbalance of carriers in QLEDs, which in turn affects the light-emitting efficiency of QLEDs.

### SUMMARY

The present disclosure provides a quantum dot light-emitting device and a method of preparing the same, a display substrate, and a display apparatus, to address deficiencies in the related art.

According to a first aspect of embodiments of the present disclosure, there is provided a quantum dot light-emitting device including a first electrode layer, a light-emitting layer, and a second electrode layer, the light-emitting layer being provided between the first electrode layer and the second electrode layer, and the light-emitting layer including quantum dots and electrolytes, where the quantum dots are provided between the electrolytes in a direction from the first electrode layer to the second electrode layer; and
the electrolytes undergo an electrochemical reaction in the presence of an electric field to provide an equal number of electrons and holes.

In an embodiment, the electrolyte includes polyethylene oxide or a polyethylene oxide derivative.

In an embodiment, in a case that the electrolyte includes the polyethylene oxide derivative, the polyethylene oxide derivative includes polyethylene oxide end group and crown ether.

In an embodiment, the electrolyte further includes an inorganic salt.

In an embodiment, the inorganic salt includes a sulfonate.

In an embodiment, a chemical formula of the inorganic salt is KCF₃SO₃, LiCF₃SO₃, NaCF₃SO₃, RbCF₃SO₃, or CsCF₃SO₃.

In an embodiment, the electrolyte further includes an organic salt.

In an embodiment, the organic salt includes a trifluoromethane sulfonate or an imidazolium.

In an embodiment, the electrolyte includes a crown ether.

In an embodiment, the crown ether has a structural formula of:

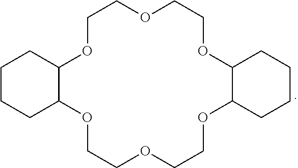 [SMILES: C1CCC2OCCOCCOC3CCCCC3OCCOCCOC2C1]

In an embodiment, the electrolyte further includes an ionic liquid.

In an embodiment, the ionic liquid includes an organic salt.

In an embodiment, the organic salt includes a trifluoromethane sulfonate.

In an embodiment, the ionic liquid has a structural formula of

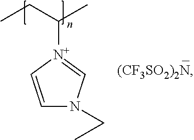

where n is a positive integer.

In an embodiment, the organic salt includes an imidazolium.

In an embodiment, the ionic liquid has a structural formula of

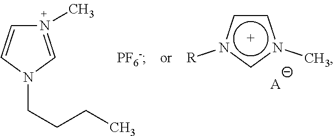

where A is PF₆⁻ or BF₄⁻.

In an embodiment, the light-emitting layer includes a mixture of the quantum dots and the electrolytes.

In an embodiment, the light-emitting layer further includes a first electrolyte layer and a quantum dot light-emitting layer, the quantum dot light-emitting layer being provided on a side of the first electrolyte layer facing the first electrode layer, the first electrolyte layer including the electrolytes, and the quantum dot light-emitting layer including a mixture of the quantum dots and the electrolytes.

In an embodiment, the light-emitting layer further includes a first electrolyte layer and a quantum dot light-emitting layer, the quantum dot light-emitting layer being provided on a side of the first electrolyte layer facing the second electrode layer, the second electrolyte layer including the electrolytes, and the quantum dot light-emitting layer including a mixture of the quantum dots and the electrolytes.

In an embodiment, the light-emitting layer further includes a first electrolyte layer, a quantum dot light-emitting layer, and a second electrolyte layer, the quantum dot light-emitting layer being provided between the first electrolyte layer and the second electrolyte layer, the first electrolyte layer and the second electrolyte layer including the electrolytes, and the quantum dot light-emitting layer including the quantum dots.

In an embodiment, the light-emitting layer further includes a first electrolyte layer, a quantum dot light-emitting layer, and a second electrolyte layer, the quantum dot light-emitting layer being provided between the first electrolyte layer and the second electrolyte layer, the first electrolyte layer and the second electrolyte layer including the electrolytes, and the quantum dot light-emitting layer including a mixture of the quantum dots and the electrolytes.

In an embodiment, the quantum dot light-emitting device further includes a hole injection layer, a hole transport layer, and an electron transport layer, the hole injection layer being provided between the first electrode layer and the light-emitting layer, the hole transport layer being provided between the hole injection layer and the light-emitting layer, and the electron transport layer being provided between the light-emitting layer and the second electrode layer.

According to a second aspect of embodiments of the present disclosure, there is provided a method of preparing a quantum dot light-emitting device, which is configured to prepare the above quantum dot light-emitting device, the method including:
forming the first electrode layer, the light-emitting layer, and the second electrode layer.

In an embodiment, forming the first electrode layer, the light-emitting layer, and the second electrode layer includes:
forming the first electrode layer;
forming the light-emitting layer on the first electrode layer; and
forming the second electrode layer on a side of the light-emitting layer facing away from the first electrode layer.

In an embodiment, the quantum dot light-emitting device further includes a hole injection layer, a hole transport layer, and an electron transport layer, the hole injection layer being provided on a side of the first electrode layer facing the light-emitting layer, the hole transport layer being provided on a side of the hole injection layer facing the light-emitting layer, and the electron transport layer being provided between the light-emitting layer and the second electrode layer; before forming the light-emitting layer, the method further includes:
forming the hole injection layer on the first electrode layer; and
forming the hole transport layer on a side of the hole injection layer facing away from the first electrode layer; and
after forming the light-emitting layer and before forming the second electrode layer, the method further includes:
forming the electron transport layer on the side of the light-emitting layer facing away from the first electrode layer.

In an embodiment, the light-emitting layer further includes a first electrolyte layer and a quantum dot light-emitting layer, the quantum dot light-emitting layer being provided on a side of the first electrolyte layer facing the first electrode layer, the second electrolyte layer including the electrolytes, and the quantum dot light-emitting layer including a mixture of the quantum dots and the electrolytes; and
forming the light-emitting layer includes:
forming the quantum dot light-emitting layer on the first electrode layer; and
forming the first electrolyte layer.

In an embodiment, the light-emitting layer further includes a first electrolyte layer and a quantum dot light-emitting layer, the quantum dot light-emitting layer being provided on a side of the first electrolyte layer facing the second electrode layer, the second electrolyte layer including the electrolytes, and the quantum dot light-emitting layer including a mixture of the quantum dots and the electrolytes; and
forming the light-emitting layer includes:
forming the first electrolyte layer on the first electrode layer; and
forming the quantum dot light-emitting layer.

In an embodiment, the light-emitting layer includes a first electrolyte layer, a quantum dot light-emitting layer, and a second electrolyte layer, the quantum dot light-emitting layer being provided between the first electrolyte layer and the second electrolyte layer, the first electrolyte layer and the second electrolyte layer including the electrolytes, and the quantum dot light-emitting layer including the quantum dots; and forming the light-emitting layer includes:
forming the first electrolyte layer on the first electrode layer;
forming the quantum dot light-emitting layer on a side of the first electrolyte layer facing away from the first electrode layer; and
forming the second electrolyte layer on a side of the quantum dot light-emitting layer facing away from the first electrolyte layer.

In an embodiment, the light-emitting layer includes a first electrolyte layer, a quantum dot light-emitting layer, and a second electrolyte layer, the quantum dot light-emitting layer being provided between the first electrolyte layer and the second electrolyte layer, the first electrolyte layer and the second electrolyte layer including the electrolytes, and the quantum dot light-emitting layer including a mixture of the quantum dots and the electrolytes; and forming the light-emitting layer includes:
forming the first electrolyte layer on the first electrode layer;
forming the quantum dot light-emitting layer on a side of the first electrolyte layer facing away from the first electrode layer; and
forming the second electrolyte layer on a side of the quantum dot light-emitting layer facing away from the first electrolyte layer.

In an embodiment, forming the first electrode layer, the light-emitting layer, and the second electrode layer includes:
forming the second electrode layer;
forming the light-emitting layer on the second electrode layer; and
forming the first electrode layer on a side of the light-emitting layer facing away from the second electrode layer.

In an embodiment, the quantum dot light-emitting device further includes a hole injection layer, a hole transport layer, and an electron transport layer, the hole injection layer being provided on a side of the first electrode layer facing the light-emitting layer, the hole transport layer being provided on a side of the hole injection layer facing the light-emitting layer, and the electron transport layer being provided between the light-emitting layer and the second electrode layer; before forming the light-emitting layer, the method further includes:
forming the electron transport layer on the second electrode layer; and
after forming the light-emitting layer and before forming the first electrode layer, the method further includes:

forming the hole transport layer on the side of the light-emitting layer facing away from the second electrode layer; and
forming the hole injection layer on a side of the hole transport layer facing away from the second electrode layer.

In an embodiment, the light-emitting layer further includes a first electrolyte layer and a quantum dot light-emitting layer, the quantum dot light-emitting layer being provided on a side of the first electrolyte layer facing the first electrode layer, the second electrolyte layer including the electrolytes, and the quantum dot light-emitting layer including a mixture of the quantum dots and the electrolytes; and
forming the light-emitting layer includes:
forming the first electrolyte layer on the second electrode layer; and
forming the quantum dot light-emitting layer.

In an embodiment, the light-emitting layer further includes a first electrolyte layer and a quantum dot light-emitting layer, the quantum dot light-emitting layer being provided on a side of the first electrolyte layer facing the second electrode layer, the second electrolyte layer including the electrolytes, and the quantum dot light-emitting layer including a mixture of the quantum dots and the electrolytes; and
forming the light-emitting layer includes:
forming the quantum dot light-emitting layer on the second electrode layer; and
forming the first electrolyte layer.

In an embodiment, the light-emitting layer includes a first electrolyte layer, a quantum dot light-emitting layer, and a second electrolyte layer, the quantum dot light-emitting layer being provided between the first electrolyte layer and the second electrolyte layer, the first electrolyte layer and the second electrolyte layer including the electrolytes, and the quantum dot light-emitting layer including the quantum dots; and forming the light-emitting layer includes:
forming the second electrolyte layer on the second electrode layer;
forming the quantum dot light-emitting layer on a side of the second electrolyte layer facing away from the second electrode layer; and
forming the first electrolyte layer on a side of the quantum dot light-emitting layer facing away from the second electrolyte layer.

In an embodiment, the light-emitting layer includes a first electrolyte layer, a quantum dot light-emitting layer, and a second electrolyte layer, the quantum dot light-emitting layer being provided between the first electrolyte layer and the second electrolyte layer, the first electrolyte layer and the second electrolyte layer including the electrolytes, and the quantum dot light-emitting layer including a mixture of the quantum dots and the electrolytes; and forming the light-emitting layer includes:
forming the second electrolyte layer on the second electrode layer;
forming the quantum dot light-emitting layer on a side of the second electrolyte layer facing away from the second electrode layer; and
forming the first electrolyte layer on a side of the quantum dot light-emitting layer facing away from the second electrolyte layer.

According to a third aspect of embodiments of the present disclosure, there is provided a display substrate including the quantum dot light-emitting device as described above.

According to a fourth aspect of embodiments of the present disclosure, there is provided a display apparatus including the above display substrate.

### BRIEF DESCRIPTION OF THE DRAWINGS

FIG. 1 is a schematic structural diagram illustrating a quantum dot light-emitting device according to an embodiment of the present disclosure.

FIGS. 2 to 6 are schematic diagrams illustrating an operating principle of a quantum dot light-emitting device according to an embodiment of the present disclosure.

FIGS. 7 and 8 are schematic diagrams illustrating operating states of a quantum dot light-emitting device according to an embodiment of the present disclosure in different time periods.

FIG. 9 is a schematic structural diagram illustrating a quantum dot light-emitting device according to another embodiment of the present disclosure.

FIG. 10 is a flowchart illustrating a method of preparing a quantum dot light-emitting device according to an embodiment of the present disclosure.

FIG. 11 is a flowchart illustrating a method of preparing a quantum dot light-emitting device according to another embodiment of the present disclosure.

FIG. 12 is a flowchart illustrating a method of preparing a quantum dot light-emitting device according to another embodiment of the present disclosure.

### DETAILED DESCRIPTION OF THE EMBODIMENTS

In order to make the foregoing objectives, features and advantages of the present disclosure more apparent and understandable, specific embodiments of the present disclosure will be described in detail below in connection with the accompanying drawings.

An embodiment of the present disclosure provides a quantum dot light-emitting device. As shown in FIG. 1, the quantum dot light-emitting device includes a first electrode layer 11, a light-emitting layer 14, and a second electrode layer 16.

As shown in FIG. 1, the light-emitting layer 14 is provided between the first electrode layer 11 and the second electrode layer 16, and the light-emitting layer 14 includes quantum dots (not shown) and electrolytes (not shown). The quantum dots are provided between the electrolytes in a direction Z from the first electrode layer 11 to the second electrode layer 16. The electrolytes undergo an electrochemical reaction in the presence of an electric field to provide an equal number of electrons and holes.

In this embodiment, a quantum dot light-emitting device includes a first electrode layer, a light-emitting layer, and a second electrode layer, the light-emitting layer being provided between the first electrode layer and the second electrode layer, and the light-emitting layer including quantum dots and electrolytes, where the quantum dots are provided between the electrolytes in a direction from the first electrode layer to the second electrode layer; and the electrolytes can undergo an electrochemical reaction in the presence of an electric field to provide an equal number of electrons and holes. Therefore, when an electric field is applied between the first electrode layer and the second electrode layer, the electrolytes can undergo an electrochemical reaction to provide an equal number of electrons and holes, such that the electrons and holes injected into the quantum dots are balanced, which is conducive to improving imbalance of carriers injected into the quantum dot light-emitting device, and thus improving the light-emitting efficiency of the quantum dot light-emitting device.

The quantum dot light-emitting device according to embodiments of the present disclosure has been briefly introduced above. The quantum dot light-emitting device according to embodiments of the present disclosure will be described in detail below.

An embodiment of the present disclosure further provides a quantum dot light-emitting device. As shown in FIG. 1, the quantum dot light-emitting device includes a first electrode layer 11, a hole injection layer 12, a hole transport layer 13, a light-emitting layer 14, an electron transport layer 15, and a second electrode layer 16. The first electrode layer 11, the hole injection layer 12, the hole transport layer 13, the light-emitting layer 14, the electron transport layer 15, and the second electrode layer 16 are sequentially laminated in a direction Z from the first electrode layer 11 to the second electrode layer 16.

In this embodiment, the first electrode layer 11 may be an anode. The first electrode layer 11 may be made of a transparent material, for example, indium tin oxide (ITO), FTO, or a conductive polymer. FTO is short for a conductive glass that is made of fluorinated SnO2. In other embodiments, the first electrode layer 11 may be made of an opaque material, for example, aluminum (Al) or silver (Ag).

In this embodiment, the hole injection layer 12 may be made of an organic injection material, for example, PEDOT:PSS. PEDOT:PSS is a high-molecular polymer including PEDOT and PSS, where PEDOT is poly(3,4-ethylenedioxythiophene), and PSS is poly(styrene sulfonic acid) sodium salt. In other embodiments, the hole injection layer 12 may be made of an inorganic oxide such as molybdenum oxide (MoOx).

In this embodiment, the hole transport layer 13 may be made of an organic material with a relatively high molecular weight, for example, PVK (poly(9-vinylcarbazole)), TFB (1,2,4,5-tetrakis(trifluoromethyl)benzene), or TPD (N,N′-diphenyl-N,N′-di(3-methylphenyl)-1,1′-biphenyl-4,4′-diamine). In other embodiments, the hole transport layer 13 may be made of an inorganic oxide, for example, nickel oxide (NiOx) or vanadium oxide (VOx). In other embodiments, the hole transport layer may be made of an organic small molecule material, for example, NPB (N,N′-diphenyl-N,N′-(1-naphthyl)-1,1′-biphenyl-4,4′-diamine), m-MTDATA (4,4′,4″-tris(N-3-methylphenyl-N-phenylamino)triphenylamine), TCTA (4,4′,4″-tris(carbazol-9-yl)triphenylamine), or TAPC (4,4′-cyclohexylidenebis[N,N-bis(4-methylphenyl)aniline]).

In this embodiment, the light-emitting layer 14 includes a mixture of the quantum dots and the electrolytes. Moreover, as shown in FIG. 1, the quantum dots are located between the electrolytes in the direction Z from the first electrode layer 11 to the second electrode layer 16. The electrolytes can undergo an electrochemical reaction under an action of an electric field to provide an equal number of electrons and holes. Therefore, when an electric field is applied between the first electrode layer 11 and the second electrode layer 16, the electrolytes can undergo an electrochemical reaction to provide an equal number of electrons and holes, such that the electrons and holes injected into the quantum dots are balanced, which is conducive to improving imbalance of carriers injected into the quantum dot light-emitting device, and thus improving the light-emitting efficiency of the quantum dot light-emitting device.

In this embodiment, the electrolyte includes polyethylene oxide (PEO) and an inorganic salt. The inorganic salt may include a sulfonate. For example, the inorganic salt may include KCF₃SO₃, LiCF₃SO₃, NaCF₃SO₃, RbCF₃SO₃, or CsCF₃SO₃. In other embodiments, the electrolyte may include polyethylene oxide and an organic salt. The organic salt may include, for example, a trifluoromethane sulfonate, or an imidazolium.

In this embodiment, the electron transport layer 15 may be made of ZnO, but is not limited thereto.

In this embodiment, the second electrode layer 16 is a cathode. The second electrode layer 16 may be made of the same material as that of the first electrode layer 11. The second electrode layer 16 may be made of a transparent material, for example, indium tin oxide, FTO, or a conductive polymer. In other embodiments, the second electrode layer 16 may be made of an opaque material, for example, aluminum (Al) or silver (Ag).

The structure of the quantum dot light-emitting device in this embodiment has been described above, and the operating principle of the quantum dot light-emitting device will be described below.

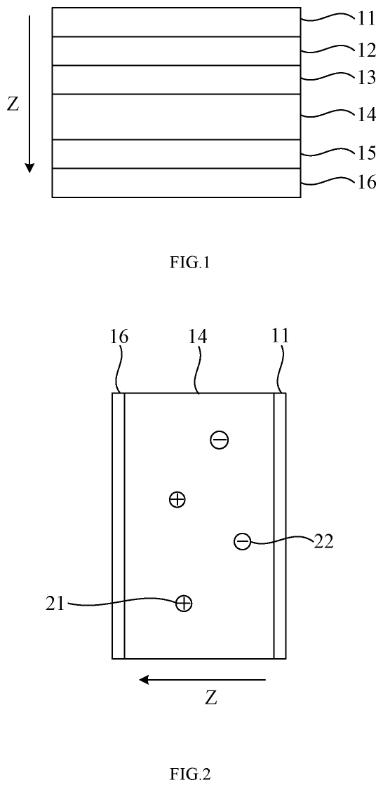

As shown in FIG. 2, the inorganic salt in the light-emitting layer 14 is ionized, and there are cations 21 and anions 22 in the light-emitting layer 14. FIG. 2 shows a case where no electric field is applied between the first electrode layer 11 and the second electrode layer 16.

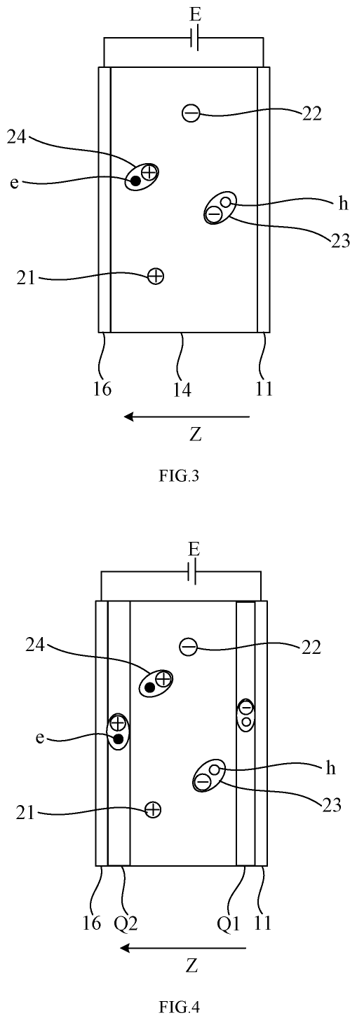

As shown in FIGS. 3 and 4, the first electrode layer 11 is connected to a positive pole of a power supply E, and the second electrode layer 16 is connected to a negative pole of the power supply E. An electric field exists between the first electrode layer 11 and the second electrode layer 16, and a direction of the electric field is from the first electrode layer 11 to the second electrode layer 16, i.e., the direction of the electric field is the direction Z. Under the action of the electric field, the electrolytes can undergo an electrochemical reaction. On a side close to the first electrode layer 11, an oxidation reaction 23 occurs to form a P-doped region Q1 and obtain holes h. On a side close to the second electrode layer 16, a reduction reaction 24 occurs to form an N-doped region Q2 and obtain electrons e. Meanwhile, the cations 21 in the light-emitting layer 14 move towards the second electrode layer 16, and the anions 22 move towards the first electrode layer 11.

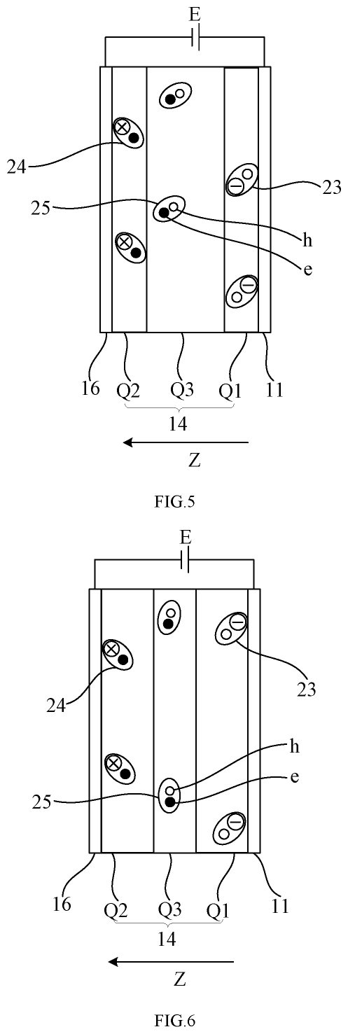

As shown in FIGS. 5 and 6, as the electrochemical reaction proceeds, the P-doped region Q1 and the N-doped region Q2 may gradually expand to the middle of the light-emitting layer 14 in the direction Z, i.e., widths of the P-doped region Q1 and the N-doped region Q2 in the direction Z may gradually increase. A region between the P-doped region Q1 and the N-doped region Q2 gradually becomes an intrinsic region Q3 with the migration of the cations 21 and the anions 22, to form a so-called p-i-n junction. The electrons e and the holes h introduced by the electrochemical reaction diffuse towards the intrinsic region Q3 and form excitons 25 therein, and the excitons 25 may be located on the quantum dots. The electron e and the hole h in the exciton 25 recombine and emit light, and the light emitted after the recombination of the electron e and the hole h may excite the quantum dot to emit light. The electrons e and the holes h injected into the quantum dots come from the electrochemical reaction, during which charge is conserved, and the light-emitting layer 14 is neutral before the electrochemical reaction. Therefore, theoretically, the electrons e and the holes h injected into the quantum dots are balanced, which is conducive to improving imbalance of carriers injected into the quantum dot light-emitting device, and thus improving the light-emitting efficiency of the quantum dot light-emitting device.

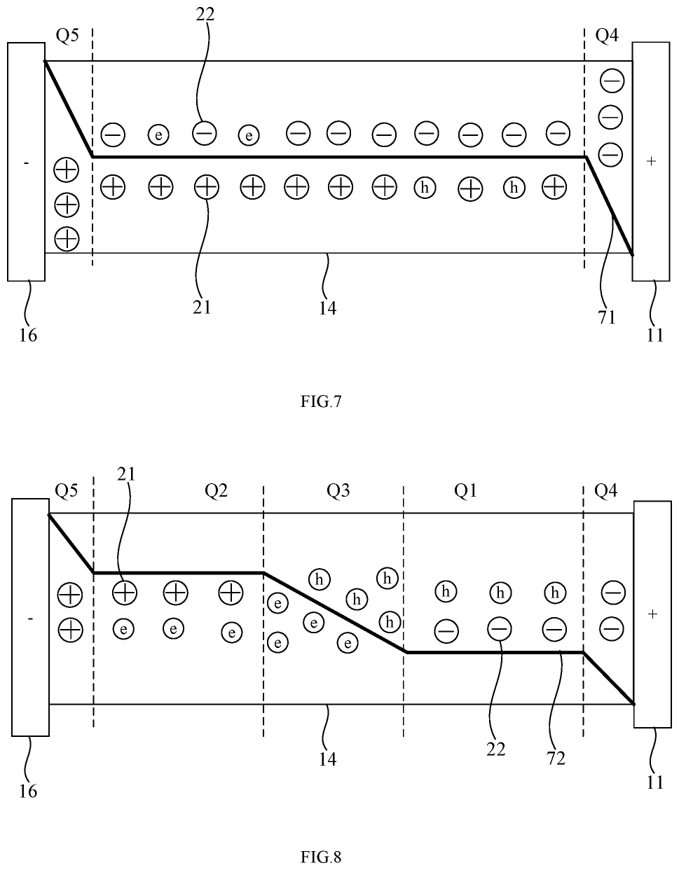

In addition, as shown in FIG. 7, after the first electrode layer 11 is connected to the positive pole of the power supply E and the second electrode layer 16 is connected to the negative pole of the power supply E, in a first time period, a first electrical double layer Q4, a second electrical double layer Q5, and a first potential gradient 71 are formed in the light-emitting layer 14. As shown in FIG. 8, as the electrochemical reaction proceeds, in a second time period, the aforementioned P-doped region Q1, N-doped region Q2 and intrinsic region Q3 are further formed in the light-emitting layer 14, and a second potential gradient 72 is formed. The second time period is after the first time period.

An embodiment of the present disclosure further provides a quantum dot light-emitting device. This embodiment differs from the above embodiments in that the electrolyte includes a polyethylene oxide derivative and an inorganic salt. For example, the polyethylene oxide derivative may include, but is not limited to, polyethylene oxide end group and crown ether. Oxygen atoms in the crown ether may bind to surfaces of the quantum dots to improve the compatibility and binding between the quantum dots and the electrolytes.

An embodiment of the present disclosure further provides a quantum dot light-emitting device. This embodiment differs from the above embodiments in that the electrolyte includes a crown ether and an ionic liquid.

In this embodiment, the crown ether has a structural formula of

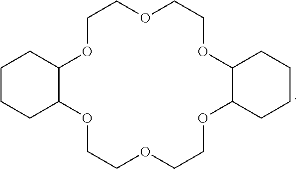 [SMILES: C1CCC2OCCOCCOC3CCCCC3OCCOCCOC2C1]

It should be noted that the structural formula of the crown ether may not be limited to the above structural formula.

In this embodiment, the ionic liquid includes an organic salt. The organic salt includes a trifluoromethane sulfonate. The ionic liquid has a structural formula of:

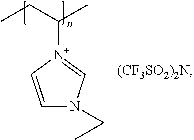

where n is a positive integer. For example, n is 1, 2, 3, or other positive integer.

An embodiment of the present disclosure further provides a quantum dot light-emitting device. This embodiment differs from the above embodiments in that the electrolyte includes a crown ether and an ionic liquid. The ionic liquid includes an organic salt. The organic salt includes an imidazolium. The ionic liquid has a structural formula of:

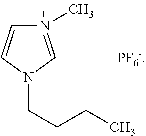

In other embodiments, the ionic liquid may have a structural formula of:

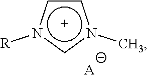

where A is PF₆⁻ or BF₄⁻, but is not limited thereto. R is an end group, which may be, for example, an alkyl chain.

An embodiment of the present disclosure further provides a quantum dot light-emitting device. As shown in FIG. 9, this embodiment differs from the embodiment shown in FIG. 1 in that the light-emitting layer 14 includes a first electrolyte layer 141, a quantum dot light-emitting layer 142, and a second electrolyte layer 143, the quantum dot light-emitting layer 142 being provided between the first electrolyte layer 141 and the second electrolyte layer 143, the first electrolyte layer 141 and the second electrolyte layer 143 including the electrolytes according to any one of the above embodiments, and the quantum dot light-emitting layer 142 including the quantum dots, but excluding the electrolytes.

In this embodiment, the first electrolyte layer 141 and the second electrolyte layer 143 are configured to prevent the quantum dot light-emitting layer 142 from contacting the hole transport layer 13, the electron transport layer 15, the first electrode layer 11, and the second electrode layer 16, and also facilitate the regulation of an electric field distribution in the quantum dot light-emitting device, thereby further regulating the injection of holes into the hole transport layer 13 and the quantum dot light-emitting layer 142, as well as regulating the injection of electrons into the electron transport layer 15 and the quantum dot light-emitting layer 142. First, a potential gradient is formed in the first electrolyte layer 141 and the second electrolyte layer 143 through an electrochemical reaction, which eventually results in recombination luminescence in the quantum dot light-emitting layer 142 in the middle.

An embodiment of the present disclosure further provides a quantum dot light-emitting device. As shown in FIG. 9, this embodiment differs from the above embodiments in that the light-emitting layer 14 includes a first electrolyte layer 141, a quantum dot light-emitting layer 142, and a second electrolyte layer 143, the first electrolyte layer 141 and the second electrolyte layer 143 including the electrolytes according to any one of the above embodiments, and the quantum dot light-emitting layer 142 including a mixture of the quantum dots and the electrolytes.

In this embodiment, the electrolyte in the first electrolyte layer 141 and the electrolyte in the second electrolyte layer 143 are the same as the electrolyte in the quantum dot light-emitting layer 142. This allows the same electrochemical reaction to occur in the first electrolyte layer 141, the quantum dot light-emitting layer 142, and the second electrolyte layer 143.

In other embodiments, the electrolyte in the first electrolyte layer 141, the electrolyte in the second electrolyte layer 143, and the electrolyte in the quantum dot light-emitting layer 142 may be different from each other, but a difference in redox potential between any two of the electrolyte in the first electrolyte layer 141, the electrolyte in the second electrolyte layer 143, and the electrolyte in the quantum dot light-emitting layer 142 is less than or equal to 0.3 eV In this way, conditions in which electrochemical reactions occur in the first electrolyte layer 141, the quantum dot light-emitting layer 142, and the second electrolyte layer 143 may be similar, or time for electrochemical reactions to occur in the same condition may be similar.

In other embodiments, the light-emitting layer 14 may further include only a first electrolyte layer 141 and a quantum dot light-emitting layer 142, the first electrolyte layer 141 being provided on a side of the quantum dot light-emitting layer 142 facing the first electrode layer 11, or the first electrolyte layer 141 being provided on a side of the quantum dot light-emitting layer 142 facing the second electrode layer 16. The first electrolyte layer 141 includes the electrolytes according to any one of the above embodiments, and the quantum dot light-emitting layer 142 includes a mixture of the quantum dots and the electrolytes.

An embodiment of the present disclosure further provides a display substrate including a driving circuit layer and the quantum dot light-emitting device according to any one of the above embodiments. The driving circuit layer is configured to drive the quantum dot light-emitting device to emit light.

An embodiment of the present disclosure further provides a display apparatus including the above display substrate and a display module.

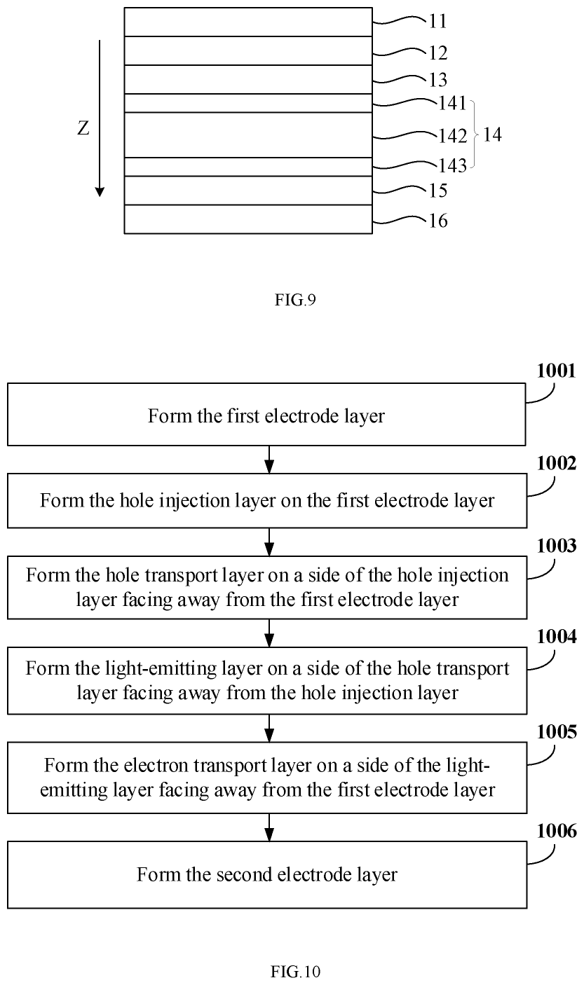

An embodiment of the present disclosure further provides a method of preparing a quantum dot light-emitting device, which is configured to prepare the quantum dot light-emitting device. As shown in FIG. 10, the method of preparing the quantum dot light-emitting device includes the following steps 1001 to 1006.

At step 1001, the first electrode layer is formed.

In this embodiment, the first electrode layer is formed on a base substrate. The base substrate may be a rigid base substrate, which may include glass, for example. In other embodiments, the base substrate may be a flexible base substrate, which may be made of, for example, PET (polyethylene terephthalate), but is not limited thereto.

In this embodiment, the first electrode layer may be an anode. The first electrode layer may be made of a transparent material, for example, indium tin oxide (ITO), FTO, or a conductive polymer. In other embodiments, the first electrode layer may be made of an opaque material, for example, aluminum (Al) and silver (Ag).

At step 1002, the hole injection layer is formed on the first electrode layer.

In this embodiment, the hole injection layer is made of an organic material, e.g., PEDOT:PSS.

In this embodiment, the hole injection layer may be formed by a spin coating process.

In other embodiments, the hole injection layer may be made of an inorganic oxide such as molybdenum oxide (MoOx). The hole injection layer may be formed by a deposition process.

At step 1003, the hole transport layer is formed on a side of the hole injection layer facing away from the first electrode layer.

In this embodiment, the hole transport layer is made of an organic material, e.g., PVK, TFB, or TPD. The hole transport layer may be formed by a spin coating process.

In other embodiments, the hole transport layer may be made of an inorganic oxide, for example, nickel oxide (NiOx) or vanadium oxide (VOx). The hole transport layer may be formed by a deposition process.

At step 1004, the light-emitting layer is formed on a side of the hole transport layer facing away from the hole injection layer.

In this embodiment, the light-emitting layer 14 includes a mixture of the quantum dots and the electrolytes. The electrolyte includes polyethylene oxide (PEO) and an inorganic salt. The inorganic salt may include a sulfonate. For example, the inorganic salt may include KCF₃SO₃, LiCF₃SO₃, NaCF₃SO₃, RbCF₃SO₃, or CsCF₃SO₃. In other embodiments, the electrolyte may include polyethylene oxide and an organic salt. The organic salt may include, for example, a trifluoromethane sulfonate, or an imidazolium.

At step 1005, the electron transport layer is formed on a side of the light-emitting layer facing away from the first electrode layer.

In this embodiment, the electron transport layer 15 may be made of ZnO, and may be formed by a deposition process, but is not limited thereto.

At step 1006, the second electrode layer is formed.

In this embodiment, the second electrode layer is a cathode. The second electrode layer 16 may be made of a transparent material, for example, indium tin oxide (ITO), FTO, or a conductive polymer. In other embodiments, the second electrode layer 16 may be made of an opaque material, for example, aluminum (Al) and silver (Ag).

An embodiment of the present disclosure further provides a method of preparing a quantum dot light-emitting device. As shown in FIG. 9, this embodiment differs from the above embodiments in that the light-emitting layer 14 includes a first electrolyte layer 141, a quantum dot light-emitting layer 142, and a second electrolyte layer 143, the quantum dot light-emitting layer 142 being provided between the first electrolyte layer 141 and the second electrolyte layer 143, the first electrolyte layer 141 and the second electrolyte layer 143 including the electrolytes according to any one of the above embodiments, and the quantum dot light-emitting layer 142 including the quantum dots, but excluding the electrolytes.

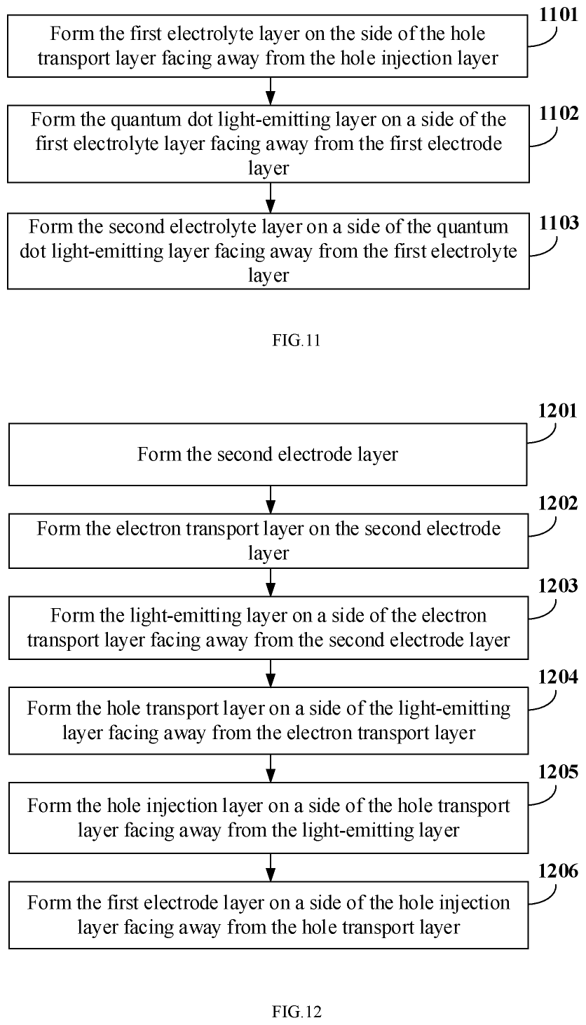

In this embodiment, as shown in FIG. 11, step 1004 may include the following steps 1101 to 1103.

At step 1101, the first electrolyte layer is formed on the side of the hole transport layer facing away from the hole injection layer.

In this embodiment, the first electrolyte layer includes the electrolytes. The electrolyte includes polyethylene oxide and an inorganic salt. The inorganic salt may include a sulfonate. For example, the inorganic salt may include KCF₃SO₃, LiCF₃SO₃, NaCF₃SO₃, RbCF₃SO₃, or CsCF₃SO₃.

At step 1102, the quantum dot light-emitting layer is formed on a side of the first electrolyte layer facing away from the first electrode layer.

In this embodiment, the quantum dot light-emitting layer includes the quantum dots but does not include the electrolytes. In other embodiments, the quantum dot light-emitting layer may include a mixture of the quantum dots and the electrolytes. The electrolyte in the quantum dot light-emitting layer, the electrolyte in the second electrolyte layer, and the electrolyte in the first electrolyte layer may be the same.

At step 1103, the second electrolyte layer is formed on a side of the quantum dot light-emitting layer facing away from the first electrolyte layer.

In this embodiment, the second electrolyte layer includes the electrolytes. The electrolyte in the second electrolyte layer is the same as the electrolyte in the first electrolyte layer.

In other embodiments, the light-emitting layer 14 may include only a first electrolyte layer 141 and a quantum dot light-emitting layer 142, with the first electrolyte layer 141 provided on a side of the quantum dot light-emitting layer 142 facing the first electrode layer 11. The first electrolyte layer 141 includes the electrolytes according to any one of the above embodiments, and the quantum dot light-emitting layer 142 includes a mixture of the quantum dots and the electrolytes. In the process of preparing the light-emitting layer 14, the first electrolyte layer may be first formed on a side of the hole transport layer facing away from the hole injection layer, and then the quantum dot light-emitting layer may be formed.

In other embodiments, the light-emitting layer 14 may include only a first electrolyte layer 141 and a quantum dot light-emitting layer 142, with the first electrolyte layer 141 provided on a side of the quantum dot light-emitting layer 142 facing the second electrode layer 16. The first electrolyte layer 141 includes the electrolytes according to any one of the above embodiments, and the quantum dot light-emitting layer 142 includes a mixture of the quantum dots and the electrolytes. In the process of preparing the light-emitting layer 14, the quantum dot light-emitting layer may be first formed on a side of the hole transport layer facing away from the hole injection layer, and then the first electrolyte layer may be formed.

An embodiment of the present disclosure further provides a method of preparing a quantum dot light-emitting device. This embodiment differs from the above embodiments in that the second electrode layer is first formed and then the first electrode layer. As shown in FIG. 12, the method of preparing the quantum dot light-emitting device may include the following steps 1201 to 1206.

At step 1201, the second electrode layer is formed.

In this embodiment, the second electrode layer is formed on a base substrate. The base substrate may be a rigid base substrate, which may include glass, for example. In other embodiments, the base substrate may be a flexible base substrate, which may be made of, for example, PET, but is not limited thereto.

In this embodiment, the second electrode layer is a cathode. The second electrode layer 16 may be made of a transparent material, for example, indium tin oxide, FTO, or a conductive polymer. In other embodiments, the second electrode layer 16 may be made of an opaque material, for example, aluminum (Al) and silver (Ag).

At step 1202, the electron transport layer is formed on the second electrode layer.

In this embodiment, the electron transport layer 15 may be made of ZnO, and may be formed by a deposition process, but is not limited thereto.

At step 1203, the light-emitting layer is formed on a side of the electron transport layer facing away from the second electrode layer.

In this embodiment, the light-emitting layer includes a mixture of the quantum dots and the electrolytes. The electrolyte includes a crown ether and an ionic liquid.

In this embodiment, the crown ether has a structural formula of:

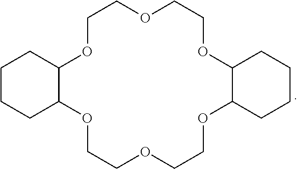 [SMILES: C1CCC2OCCOCCOC3CCCCC3OCCOCCOC2C1]

In this embodiment, the ionic liquid includes an organic salt. The organic salt includes a trifluoromethane sulfonate. The ionic liquid has a structural formula of:

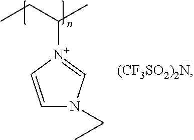

where n is a positive integer. For example, n is 1, 2, 3, or other positive integer.

In other embodiments, as shown in FIG. 9, the light-emitting layer 14 may include a first electrolyte layer 141, a quantum dot light-emitting layer 142, and a second electrolyte layer 143, the quantum dot light-emitting layer 142 being provided between the first electrolyte layer 141 and the second electrolyte layer 143, the first electrolyte layer 141 and the second electrolyte layer 143 including the electrolytes according to any one of the above embodiments, and the quantum dot light-emitting layer 142 including the quantum dots but excluding the electrolytes, or the quantum dot light-emitting layer 142 including a mixture of the quantum dots and the electrolytes. In the process of preparing the light-emitting layer 14, the second electrolyte layer is first formed on the electron transport layer. Then, the quantum dot light-emitting layer is formed on a side of the second electrolyte layer facing away from the second electrode layer. Then, the first electrolyte layer is formed on a side of the quantum dot light-emitting layer facing away from the second electrolyte layer.

In other embodiments, the light-emitting layer 14 may include only a first electrolyte layer 141 and a quantum dot light-emitting layer 142, with the first electrolyte layer 141 provided on a side of the quantum dot light-emitting layer 142 facing the first electrode layer 11. The first electrolyte layer 141 includes the electrolytes according to any one of the above embodiments, and the quantum dot light-emitting layer 142 includes a mixture of the quantum dots and the electrolytes. In the process of preparing the light-emitting layer 14, the quantum dot light-emitting layer is first formed on the electron transport layer, and then the first electrolyte layer is formed.

In other embodiments, the light-emitting layer 14 may include only a first electrolyte layer 141 and a quantum dot light-emitting layer 142, with the first electrolyte layer 141 provided on a side of the quantum dot light-emitting layer 142 facing the second electrode layer 16. The first electrolyte layer 141 includes the electrolytes according to any one of the above embodiments, and the quantum dot light-emitting layer 142 includes a mixture of the quantum dots and the electrolytes. In the process of preparing the light-emitting layer 14, the first electrolyte layer may be first formed on the electron transport layer, and then the quantum dot light-emitting layer is formed.

At step 1204, the hole transport layer is formed on a side of the light-emitting layer facing away from the electron transport layer.

In this embodiment, the hole transport layer may be made of an organic small molecule material, for example, NPB, m-MTDATA, TCTA, or TAPC. The hole transport layer may be formed by an evaporation process without affecting the quality of other film layers.

In other embodiments, the hole transport layer may be made of an organic material with a relatively high molecular weight, e.g., PVK, TFB, or TPD. The hole transport layer may be formed by a spin coating process. In other embodiments, the hole transport layer may be made of an inorganic oxide, for example, nickel oxide (NiOx) or vanadium oxide (VOx). The hole transport layer may be formed by a deposition process.

At step 1205, the hole injection layer is formed on a side of the hole transport layer facing away from the light-emitting layer.

In this embodiment, the hole injection layer is made of an organic material, e.g., PEDOT:PSS. The hole injection layer may be formed by a spin coating process.

In other embodiments, the hole injection layer may be made of an inorganic oxide such as molybdenum oxide (MoOx). The hole injection layer may be formed by a deposition process.

At step 1206, the first electrode layer is formed on a side of the hole injection layer facing away from the hole transport layer.

In this embodiment, the first electrode layer may be an anode. The first electrode layer may be made of a transparent material, for example, indium tin oxide (ITO), FTO, or a conductive polymer. In other embodiments, the first electrode layer may be made of an opaque material, for example, aluminum (Al) and silver (Ag).

It should be noted that the display apparatus in the present embodiment may include electronic paper, mobile phone, tablet computer, TV set, notebook computer, digital photo frame, navigator, and any other product or component with a display function.

Formation processes used in the above process may include, for example, a film forming process such as deposition and sputtering, and a patterning process such as etching.

It should be noted that in the drawings, sizes of layers and areas may be exaggerated for clarity of illustration. Moreover, it may be understood that when an element or layer is referred to as being “on” another element or layer, it may be directly on the other element, or there may be an intermediate layer. Further, it may be understood that when an element or layer is referred to as being “under” another element or layer, it may be directly under the other element, or more than one intermediate layer or element may be present. In addition, it may be understood that when a layer or element is referred to as being “between” two layers or elements, it may be the only layer between the two layers or elements, or more than one intermediate layer or element may be present. Similar reference numerals indicate similar elements throughout.

In the present disclosure, terms “first” and “second” are used for descriptive purposes only, and are not to be understood as indicating or implying relative importance. Term “a plurality of” refers to two or more, unless expressly limited otherwise.

Although the present disclosure has been disclosed as above, the present disclosure is not limited thereto. Any person skilled in the art may make various changes and modifications without departing from the spirit and scope of the present disclosure. Therefore, the scope of protection of the present disclosure should be subject to the scope defined in the claims.

1. A quantum dot light-emitting device, comprising a first electrode layer, a light-emitting layer, and a second electrode layer, the light-emitting layer being provided between the first electrode layer and the second electrode layer, and the light-emitting layer comprising quantum dots and electrolytes, wherein the quantum dots are provided between the electrolytes in a direction from the first electrode layer to the second electrode layer; and
the electrolytes undergo an electrochemical reaction in the presence of an electric field to provide an equal number of electrons and holes.

2. The quantum dot light-emitting device according to claim 1, wherein the electrolyte comprises polyethylene oxide or a polyethylene oxide derivative.

3. The quantum dot light-emitting device according to claim 2, wherein in a case that the electrolyte comprises the polyethylene oxide derivative, the polyethylene oxide derivative comprises polyethylene oxide end group and crown ether.

4. The quantum dot light-emitting device according to claim 2, wherein the electrolyte further comprises an inorganic salt,
the inorganic salt comprises a sulfonate, and
a chemical formula of the inorganic salt is KCF₃SO₃, LiCF₃SO₃, NaCF₃SO₃, RbCF₃SO₃, or CsCF₃SO₃.

5-6. (canceled)

7. The quantum dot light-emitting device according to claim 2, wherein the electrolyte further comprises an organic salt, and
the organic salt comprises a trifluoromethane sulfonate or an imidazolium.

8. (canceled)

9. The quantum dot light-emitting device according to claim 1, wherein the electrolyte comprises a crown ether.

10. The quantum dot light-emitting device according to claim 9, wherein the crown ether has a structural formula of:

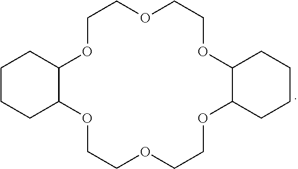 [SMILES: C1CCC2OCCOCCOC3CCCCC3OCCOCCOC2C1]

11. The quantum dot light-emitting device according to claim 9, wherein the electrolyte further comprises an ionic liquid, and
the ionic liquid comprises an organic salt.

12. (canceled)

13. The quantum dot light-emitting device according to claim 11, wherein the organic salt comprises a trifluoromethane sulfonate, and
the ionic liquid has a structural formula of: 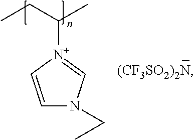
wherein n is a positive integer.

14. (canceled)

15. The quantum dot light-emitting device according to claim 11, wherein the organic salt comprises an imidazolium, and
the ionic liquid has a structural formula of: 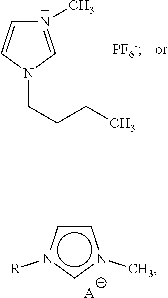
wherein A is PF₆⁻ or BF₄⁻.

16-17. (canceled)

18. The quantum dot light-emitting device according to claim 1, wherein the light-emitting layer further comprises a first electrolyte layer and a quantum dot light-emitting layer, the quantum dot light-emitting layer being provided on a side of the first electrolyte layer facing the first electrode layer, the first electrolyte layer comprising the electrolytes, and the quantum dot light-emitting layer comprising a mixture of the quantum dots and the electrolytes, or
wherein the light-emitting layer further comprises a first electrolyte layer and a quantum dot light-emitting layer, the quantum dot light-emitting layer being provided on a side of the first electrolyte layer facing the second electrode layer, the first electrolyte layer comprising the electrolytes, and the quantum dot light-emitting layer comprising a mixture of the quantum dots and the electrolytes.

19. (canceled)

20. The quantum dot light-emitting device according to claim 1, wherein the light-emitting layer further comprises a first electrolyte layer, a quantum dot light-emitting layer, and a second electrolyte layer, the quantum dot light-emitting layer being provided between the first electrolyte layer and the second electrolyte layer, the first electrolyte layer and the second electrolyte layer comprising the electrolytes, and the quantum dot light-emitting layer comprising the quantum dots, or the quantum dot light-emitting layer comprising a mixture of the quantum dots and the electrolytes.

21. (canceled)

22. The quantum dot light-emitting device according to claim 1, further comprising a hole injection layer, a hole transport layer, and an electron transport layer, the hole injection layer being provided between the first electrode layer and the light-emitting layer, the hole transport layer being provided between the hole injection layer and the light-emitting layer, and the electron transport layer being provided between the light-emitting layer and the second electrode layer.

23. A method of preparing a quantum dot light-emitting device, which is configured to prepare the quantum dot light-emitting device according to claim 1, the method comprising:
forming the first electrode layer, the light-emitting layer, and the second electrode layer.

24. The method according to claim 23, wherein forming the first electrode layer, the light-emitting layer, and the second electrode layer comprises:
forming the first electrode layer;
forming the light-emitting layer on the first electrode layer; and
forming the second electrode layer on a side of the light-emitting layer facing away from the first electrode layer.

25. The method according to claim 24, wherein the quantum dot light-emitting device further comprises a hole injection layer, a hole transport layer, and an electron transport layer, the hole injection layer being provided on a side of the first electrode layer facing the light-emitting layer, the hole transport layer being provided on a side of the hole injection layer facing the light-emitting layer, and the electron transport layer being provided between the light-emitting layer and the second electrode layer; before forming the light-emitting layer, the method further comprises:
forming the hole injection layer on the first electrode layer; and
forming the hole transport layer on a side of the hole injection layer facing away from the first electrode layer; and
after forming the light-emitting layer and before forming the second electrode layer, the method further comprises:
forming the electron transport layer on the side of the light-emitting layer facing away from the first electrode layer.

26. The method according to claim 24, wherein the light-emitting layer further comprises a first electrolyte layer and a quantum dot light-emitting layer, the quantum dot light-emitting layer being provided on a side of the first electrolyte layer facing the first electrode layer, the first electrolyte layer comprising the electrolytes, and the quantum dot light-emitting layer comprising a mixture of the quantum dots and the electrolytes; and
forming the light-emitting layer comprises:
forming the quantum dot light-emitting layer on the first electrode layer; and
forming the first electrolyte layer, or
wherein the light-emitting layer further comprises a first electrolyte layer and a quantum dot light-emitting layer, the quantum dot light-emitting layer being provided on a side of the first electrolyte layer facing the second electrode layer, the first electrolyte layer comprising the electrolytes, and the quantum dot light-emitting layer comprising a mixture of the quantum dots and the electrolytes; and
forming the light-emitting layer comprises:
forming the first electrolyte layer on the first electrode layer; and
forming the quantum dot light-emitting layer.

27. (canceled)

28. The method according to claim 24, wherein the light-emitting layer comprises a first electrolyte layer, a quantum dot light-emitting layer, and a second electrolyte layer, the quantum dot light-emitting layer being provided between the first electrolyte layer and the second electrolyte layer, the first electrolyte layer and the second electrolyte layer comprising the electrolytes, and the quantum dot light-emitting layer comprising the quantum dots, or the quantum dot light-emitting layer comprising a mixture of the quantum dots and the electrolytes; and forming the light-emitting layer comprises:
forming the first electrolyte layer on the first electrode layer;
forming the quantum dot light-emitting layer on a side of the first electrolyte layer facing away from the first electrode layer; and
forming the second electrolyte layer on a side of the quantum dot light-emitting layer facing away from the first electrolyte layer.

29-35. (canceled)

36. A display substrate, comprising a plurality of quantum dot light-emitting devices arranged in an array, wherein each of the quantum dot light-emitting devices comprises a first electrode layer, a light-emitting layer, and a second electrode layer, the light-emitting layer being provided between the first electrode layer and the second electrode layer, and the light-emitting layer comprising quantum dots and electrolytes, wherein the quantum dots are provided between the electrolytes in a direction from the first electrode layer to the second electrode layer; and
the electrolytes undergo an electrochemical reaction in the presence of an electric field to provide an equal number of electrons and holes.

37. A display apparatus, comprising the display substrate according to claim 36.
